(19) United States
(12) Patent Application Publication
(10) Pub. No.: US 2019/0273203 A1
(43) Pub. Date: Sep. 5, 2019

(54) MAGNETORESISTIVE EFFECT ELEMENT

(71) Applicants: TDK CORPORATION, Tokyo (JP); NATIONAL UNIVERSITY CORPORATION HOKKAIDO UNIVERSITY, Sapporo-shi (JP)

(72) Inventors: Kazuumi INUBUSHI, Tokyo (JP); Katsuyuki NAKADA, Tokyo (JP); Tetsuya UEMURA, Sapporo-shi (JP)

(73) Assignees: TDK CORPORATION, Tokyo (JP); NATIONAL UNIVERSITY CORPORATION HOKKAIDO UNIVERSITY, Sapporo-shi (JP)

(21) Appl. No.: 16/190,695

(22) Filed: Nov. 14, 2018

(30) Foreign Application Priority Data
Mar. 2, 2018 (JP) 2018-037806
Aug. 29, 2018 (JP) 2018-160649

(51) Int. Cl. H01L 43/10; H01L 43/02

(52) U.S. Cl. CPC H01L 43/10; H01L 43/12; H01L 43/02

(57) ABSTRACT

A magnetoresistive effect element according to the present disclosure includes: a first ferromagnetic layer serving as a magnetization free layer; a second ferromagnetic layer serving as a magnetization fixed layer; and a nonmagnetic spacer layer provided between the first ferromagnetic layer and the second ferromagnetic layer. At least one of the first ferromagnetic layer and the second ferromagnetic layer contains a Heusler alloy represented by Formula (1): X₂Mn_{α}Z_{β} . . . (1) where X represents at least one element selected from the group consisting of Co, Ni, Fe, Ru, and Rh, and Z represents at least one element selected from the group consisting of Si, Al, Ga, Ge, Sb, and Sn, and ⅔<α+β<2 is satisfied, thereby providing a magnetoresistive effect element in which the ferromagnetic layer of a magnetoresistance layer contains a Heusler alloy containing Mn and which provides great magnetoresistive effect.

### TECHNICAL FIELD

The present disclosure relates to a magnetoresistive effect element.

### BACKGROUND

Magnetoresistive effect elements have been expected to be used in magnetic devices, such as magnetic sensors. The magnetoresistive effect element described in Non Patent Literature 1 mentioned below includes a first half-metal ferromagnet layer, a second half-metal ferromagnet layer, and a nonmagnetic metal layer (nonmagnetic spacer layer) sandwiched between the first half-metal ferromagnet layer and the second half-metal ferromagnet layer. These three layers constitute a magnetoresistance layer.

Non Patent Literature 1: T. Iwase et. al., “Large Interface Spin-Asymmetry and Magnetoresistance in Fully Epitaxial Co₂MnSi/Ag/Co₂MnSi Current-Perpendicular-to-Plane Magnetoresistive Devices”, Applied Physics Express, Vol. 2, No. 6, 063003 (2009)

### SUMMARY

In the magnetoresistive effect element described in Non Patent Literature 1, at least one of the first half-metal ferromagnet layer and the second half-metal ferromagnet layer is composed of a Heusler alloy (CoMnSi), and the nonmagnetic spacer layer is composed of Ag. The Co, Mn and Si contained in the Heusler alloy have a stoichiometric composition (Co:Mn:Si=50.4:25.0:24.6 (=2:0.99:0.98)). Since heat treatment (annealing treatment) for ordering the crystals of the Heusler alloy is performed at the time of manufacturing the magnetoresistive effect element, Mn of the Heusler alloy sometimes diffuses into the nonmagnetic spacer layer. If Mn diffuses into the nonmagnetic spacer layer, the problem arises that the magnetoresistive effect provided by the magnetoresistive effect element is decreased. It is desired that diffusion of Mn contained in the Heusler alloy into the nonmagnetic spacer layer be suppressed.

The present disclosure has been made in view of the above problems, and an object of the present disclosure is to provide a magnetoresistive effect element in which the ferromagnetic layer of a magnetoresistance layer contains a Heusler alloy containing Mn and which provides large magnetoresistive effect.

A magnetoresistive effect element according to one aspect of the present disclosure comprises a first ferromagnetic layer serving as a magnetization free layer; a second ferromagnetic layer serving as a magnetization fixed layer; and a nonmagnetic spacer layer provided between the first ferromagnetic layer and the second ferromagnetic layer. At least one of the first ferromagnetic layer and the second ferromagnetic layer contains a Heusler alloy represented by Formula (1).

X₂Mn_{α}Zβ (1)

In Formula (1), X represents at least one element selected from the group consisting of Co, Ni, Fe, Ru, and Rh, and Z represents at least one element selected from the group consisting of Si, Al, Ga, Ge, Sb, and Sn, and ⅔<α+β<2 is satisfied.

In the Heusler alloy X₂Mn_{α}Z_{β} in this magnetoresistive effect element, α+β<2 is satisfied and the total ratio of Mn and Z in X₂Mn_{α}Z_{β} is smaller than ½, so that the Heusler alloy X₂Mn_{α}Z_{β} hardly contains excess Mn. Accordingly, Mn easily enters the Mn site correctly while excess Mn is hardly contained, so that X easily enters the Mn site to form a X_{Mn} antisite, thereby suppressing the diffusion of Mn into the nonmagnetic spacer layer. In addition, in the Heusler alloy X₂Mn_{α}Z_{β}, ⅔<α+β is satisfied and the total ratio of Mn and Z in the Heusler alloy X₂Mn_{α}Z_{β} is greater than ¼. Accordingly, the composition of the Heusler alloy X₂Mn_{α}Z_{β} does not largely deviate from the stoichiometric composition, so that the spin polarizability easily increases. The resulting magnetoresistive effect element provides large magnetoresistive effect.

In the magnetoresistive effect element according to one aspect of the present disclosure, β<(2+α)/3 may further be satisfied in the Formula (1).

In this magnetoresistive effect element, the ratio of Z in the Heusler alloy X₂Mn_{α}Z_{β} is less than ¼, so that Mn easily enters the Z site to form a Mn_{Z} antisite. Movement of Mn more easily stays within the crystalline structure of the Heusler alloy X₂Mn_{α}Z_{β} layer, thereby further suppressing diffusion of Mn into areas other than the Heusler alloy layer.

In the magnetoresistive effect element according to one aspect of the present disclosure, β>α may further be satisfied in the Formula (1).

In this magnetoresistive effect element, β>α is satisfied and Mn is less than Z, so that movement of Mn into the nonmagnetic spacer layer is further suppressed.

In the magnetoresistive effect element according to one aspect of the present disclosure, Z may be Si in the Formula (1).

In this magnetoresistive effect element, when the Heusler alloy contains Si, the Curie temperature is high, so that large magnetoresistive effect is produced even at room temperature.

In the magnetoresistive effect element according to one aspect of the present disclosure, at least one of a third ferromagnetic layer serving as a magnetization free layer and a fourth ferromagnetic layer serving as a magnetization fixed layer may further be comprised, the third ferromagnetic layer and the fourth ferromagnetic layer may contain the Heusler alloy represented by Formula (2), the first ferromagnetic layer may be provided between the third ferromagnetic layer and the nonmagnetic spacer layer, and the second ferromagnetic layer may be provided between the fourth ferromagnetic layer and the nonmagnetic spacer layer.

D₂Mn_{δ}E_{θ} (2)

In Formula (2), D represents at least one element selected from the group consisting of Co, Ni, Fe, Ru, and Rh, and E represents at least one element selected from the group consisting of Si, Al, Ga, Ge, Sb, and Sn, and 2<δ+θ<2.6 is satisfied.

In this magnetoresistive effect element, in the Heusler alloy D₂Mn_{δ}E_{θ}, when 2<δ+θ<2.6, the effect of the formation of antisites, such as a D_{Mn} antisite and a D_{E} antisite, to the spin polarizability decreases, allowing the third ferromagnetic layer and the fourth ferromagnetic layer to easily maintain half metal characteristics. Consequently, the third ferromagnetic layer serves as a magnetization free layer together with the first ferromagnetic layer, and the spin polarizability of the magnetization free layer increases. Further, the fourth ferromagnetic layer serves as a magnetization fixed layer together with the second ferromagnetic layer, so that the spin polarizability of the magnetization fixed layer increases. On the other hand, in the Heusler alloy D₂Mn_{δ}E_{θ}, 2<δ+θ<2.6 is satisfied, so that the third ferromagnetic layer and the fourth ferromagnetic layer contain excess Mn. In this magnetoresistive effect element, the first ferromagnetic layer provided between the third ferromagnetic layer and the nonmagnetic spacer layer can suppress movement of Mn from the third ferromagnetic layer to the nonmagnetic spacer layer. Further, the second ferromagnetic layer provided between the fourth ferromagnetic layer and the nonmagnetic spacer layer can suppress movement of Mn from the fourth ferromagnetic layer to the nonmagnetic spacer layer.

A magnetoresistive effect element according to another aspect of the present disclosure comprises a first ferromagnetic layer serving as a magnetization free layer; a second ferromagnetic layer serving as a magnetization fixed layer; and a nonmagnetic spacer layer provided between the first ferromagnetic layer and the second ferromagnetic layer. At least one of the first ferromagnetic layer and the second ferromagnetic layer contains a Heusler alloy represented by Formula (3).

X₂(Mn_{ε}G_{η})_{α}Z_{β} (3)

In Formula (3), X represents at least one element selected from the group consisting of Co, Ni, Fe, Ru, and Rh, G represents at least one of the elements of Fe and Cr, X does not contain Fe when G contains Fe, Z represents at least one element selected from the group consisting of Si, Al, Ga, Ge, Sb, and Sn, and ⅔<α+β<2, 0<ε<1, and 0<η<1 are satisfied.

In the Heusler alloy X₂(Mn_{ε}G_{η})_{α}Z_{β} in this magnetoresistive effect element, α+β<2 and 0<ε<1 are satisfied and the total ratio of Mn and Z in X₂(Mn_{ε}G_{η})_{α}Z_{β} is smaller than ½, so that the Heusler alloy X₂(Mn_{ε}G_{η})_{α}Z_{β} hardly contains excess Mn. Accordingly, Mn easily enters the Mn site correctly while excess Mn is hardly contained, so that X easily enters the Mn site to form a X_{Mn} antisite, thereby suppressing the diffusion of Mn into the nonmagnetic spacer layer. In addition, in the Heusler alloy X₂(Mn_{E}G_{η})_{α}Z_{β}, ⅔<α+β is satisfied and the total ratio of Mn, G, and Z in the Heusler alloy X₂(Mn_{ε}G_{η})_{α}Z_{β} can be greater than ¼. Accordingly, the composition of the Heusler alloy X₂(Mn_{ε}G_{η})_{α}Z_{β} does not largely deviate from the stoichiometric composition, so that the spin polarizability easily increases. The resulting magnetoresistive effect element provides large magnetoresistive effect.

In the magnetoresistive effect element according to the other aspect of the present disclosure, β<(2+α)/3 may further be satisfied in the Formula (3).

In this magnetoresistive effect element, the ratio of Z in the Heusler alloy X₂(Mn_{ε}G_{η})_{α}Z_{β} is less than ¼, so that Mn satisfy enters the Z site to form a Mn_{Z} antisit. Movement of Mn more easily stays within the crystalline structure of the Heusler alloy X₂(Mn_{ε}G_{η})_{α}Z_{β} layer, thereby further suppressing diffusion of Mn into areas other than the Heusler alloy layer.

In the magnetoresistive effect element according to the other aspect of the present disclosure, β>α may further be satisfied in the Formula (3).

In this magnetoresistive effect element, β>α and 0<ε<1 are satisfied and Mn is less than Z, so that movement of Mn into the nonmagnetic spacer layer is further suppressed.

In the magnetoresistive effect element according to the other aspect of the present disclosure, Z may be Si in the Formula (3).

In this magnetoresistive effect element, when the Heusler alloy contains Si, the Curie temperature is high, so that large magnetoresistive effect is produced even at room temperature.

In the magnetoresistive effect element according to the other aspect of the present disclosure, at least one of a third ferromagnetic layer serving as a magnetization free layer and a fourth ferromagnetic layer serving as a magnetization fixed layer may further be comprised, the third ferromagnetic layer and the fourth ferromagnetic layer may contain the Heusler alloy represented by Formula (4), the first ferromagnetic layer may be provided between the third ferromagnetic layer and the nonmagnetic spacer layer, and the second ferromagnetic layer may be provided between the fourth ferromagnetic layer and the nonmagnetic spacer layer.

D₂(Mn_{ε}G_{η})_{δ}E_{θ} (4)

In Formula (4), D represents at least one element selected from the group consisting of Co, Ni, Fe, Ru, and Rh, G represents at least one of the elements of Fe and Cr, D does not contain Fe when G contains Fe, E represents at least one element selected from the group consisting of Si, Al, Ga, Ge, Sb, and Sn, and 2<δ+θ<2.6, 0<ε<1, and 0<η<1 are satisfied.

In this magnetoresistive effect element, in the Heusler alloy D₂(Mn_{ε}G_{η})_{δ}E_{θ}, when 2<δ+θ<2.6, the effect of the formation of antisites, such as a D_{Mn} antisite and a D_{E} antisite, to the spin polarizability decreases, allowing the third ferromagnetic layer and the fourth ferromagnetic layer to easily maintain half metal characteristics. Consequently, the third ferromagnetic layer serves as a magnetization free layer together with the first ferromagnetic layer, and the spin polarizability of the magnetization free layer increases. Further, the fourth ferromagnetic layer serves as a magnetization fixed layer together with the second ferromagnetic layer, so that the spin polarizability of the magnetization fixed layer increases. On the other hand, in the Heusler alloy D₂(Mn_{ε}G_{η})_{α}E_{θ}, 2<δ+θ<2.6 is satisfied, so that the third ferromagnetic layer and the fourth ferromagnetic layer can contain excess Mn. In this magnetoresistive effect element, the first ferromagnetic layer provided between the third ferromagnetic layer and the nonmagnetic spacer layer can suppress movement of Mn from the third ferromagnetic layer to the nonmagnetic spacer layer. Further, the second ferromagnetic layer provided between the fourth ferromagnetic layer and the nonmagnetic spacer layer can suppress movement of Mn from the fourth ferromagnetic layer to the nonmagnetic spacer layer.

In the magnetoresistive effect element according to the present disclosure, the nonmagnetic spacer layer may contain Ag or Ag-containing metal represented by Formula (A).

Ag_{γ}L_{1-γ} (A)

In Formula (A), L is at least one element selected from the group consisting of Al, Cu, Ga, Ge, As, Y, La, Sm, Yb, and Pt, and 0<γ≤1 is satisfied.

In this magnetoresistive effect element, the nonmagnetic spacer layer contains Ag or Ag-containing metal represented by Formula (A), and the lattice constant of the Ag or Ag-containing metal can be adjusted by changing the value of L and/or γ of the element. Adjustment of this lattice constant can reduce lattice mismatch between the nonmagnetic spacer layer and the first ferromagnetic layer and/or the second ferromagnetic layer. Reducing lattice mismatch improves the crystallinity of the first ferromagnetic layer and/or the second ferromagnetic layer and the nonmagnetic spacer layer, thereby producing larger magnetoresistive effect.

The present disclosure provides a magnetoresistive effect element in which the ferromagnetic layer of a magnetoresistance layer contains a Heusler alloy containing Mn and which provides large magnetoresistive effect.

### BRIEF DESCRIPTION OF THE DRAWINGS

FIG. 1 is a diagram showing the cross section of a magnetoresistive effect element according to an embodiment;

FIG. 2A is a diagram schematically showing the relationship between the values of α and β and the regions I to V in the Heusler alloy Co₂Mn_{α}Si_{β};

FIG. 2B is a diagram schematically showing the relationship between the values of α and β and the regions I to VI in the Heusler alloy Co₂Mn_{α}Si_{β};

FIG. 3 is a diagram showing the cross section of a magnetoresistive effect element according to a modification of one of the embodiments;

FIG. 4 is a diagram showing the cross section of a magnetoresistive effect element according to another embodiment;

FIG. 5 is a diagram showing the cross section of a magnetoresistive effect element according to a modification of another embodiment;

FIG. 6 is a diagram showing a magnetoresistance device capable of evaluating the MR ratio of a magnetoresistive effect element according to an example;

FIG. 7A is a diagram showing the cross section of a magnetoresistive effect element according to Example 1;

FIG. 7B is a diagram showing the cross section of a magnetoresistive effect element according to Example 3;

FIG. 7C is a diagram showing the cross section of a magnetoresistive effect element according to Example 5; and

FIG. 8 is a diagram showing the cross section of a magnetoresistive effect element according to Example 6.

### DETAILED DESCRIPTION

An embodiment of the present disclosure will now be described with reference to the accompanying drawings. Note that, in the drawings, the same component is denoted by the same reference numeral if possible. Further, ratios between the sizes of or sizes in the components in the drawings are arbitrary for the viewability of the drawings.

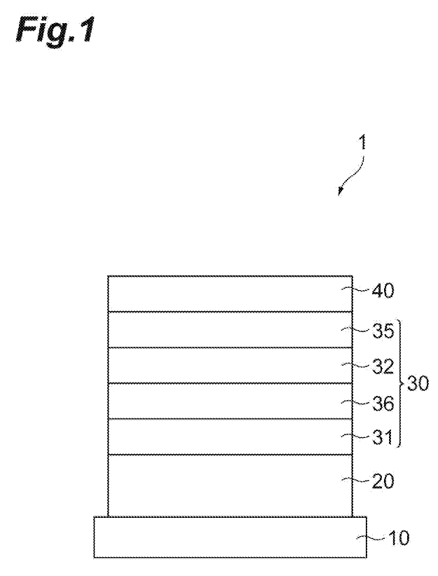

FIG. 1 is a diagram showing the cross section of a magnetoresistive effect element according to an embodiment. A magnetoresistive effect element 1 includes, for example, a substrate 10, a base layer 20, a magnetoresistance layer 30, and a cap layer 40, in this order.

Examples of the material for the substrate 10 include a single-crystal metal oxide, single-crystal silicon, single-crystal silicon with a thermal oxide film, a single-crystal sapphire, ceramic, quartz, and glass. The material contained in substrate 10 may be any material that has appropriate mechanical strength and is suitable for thermal treatment and micromachining. Examples of single-crystal metal oxide include single-crystal MgO. With a substrate containing single-crystal MgO, an epitaxial growth film is easily formed by sputtering, for example. This epitaxial growth film exhibits large magnetoresistive characteristics.

The base layer 20 is provided to improve the crystallinity of the magnetoresistance layer 30 and can also serve as an electrode for measuring magnetoresistive characteristics. The base layer 20 may include at least one metallic element selected from the group consisting of Ag, Au, Cu, Cr, V, Al, W, and Pt, an alloy of these metallic elements, or a stack body of materials composed of two or more of these metallic elements. Examples of alloy of metallic elements include cubic AgZn alloys, AgMg alloys, and NiAl alloys. A crystal orientation layer for controlling the crystal orientation of the upper layer may be provided between the base layer 20 and the substrate 10 as needed. The crystal orientation layer contains, for example, at least one of MgO, TiN, and a NiTa alloy.

The magnetoresistance layer 30 includes a first ferromagnetic layer 31 serving as a magnetization free layer, a second ferromagnetic layer 32 serving as a magnetization fixed layer, and a nonmagnetic spacer layer 36 provided between the first ferromagnetic layer 31 and the second ferromagnetic layer 32. The second ferromagnetic layer 32 is provided, for example, on the nonmagnetic spacer layer 36.

The first ferromagnetic layer 31 serving as a magnetization free layer is composed of a soft magnetic material and its magnetization direction is substantially not fixed. Therefore, when an external magnetic field of a measurement object is applied, the magnetization direction easily changes to that direction. The magnetization direction of the second ferromagnetic layer 32 serving as a magnetization fixed layer is harder to change with respect to the external magnetic field than the magnetization direction of the first ferromagnetic layer 31. It is preferable that the magnetization direction of the second ferromagnetic layer 32 be substantially fixed with respect to the external magnetic field of a measurement object and do not substantially change with respect to the external magnetic field of the measurement object. When an external magnetic field is applied to the magnetoresistance layer 30 and the relative magnetization directions of the first ferromagnetic layer 31 and the second ferromagnetic layer 32 change, the resistance of the magnetoresistance layer 30 changes and magnetoresistive effect is produced.

At least one of the first ferromagnetic layer 31 and the second ferromagnetic layer 32 contains the Heusler alloy represented by Formula (1).

X₂Mn_{α}Z_{β} (1)

In Formula (1), X represents at least one element selected from the group consisting of Co, Ni, Fe, Ru, and Rh, and Z represents at least one element selected from the group consisting of Si, Al, Ga, Ge, Sb, and Sn, and ⅔<α+β<2 is satisfied.

In this embodiment, in Formula (1), X can be Co. In a Heusler alloy, in which X is Co, the Curie temperature is sufficiently higher than room temperature, so that large magnetoresistive effect is produced even at room temperature. In addition, in Formula (1), Z can be Si. In a Heusler alloy containing Si, the Curie temperature is high, so that large magnetoresistive effect is produced even at room temperature.

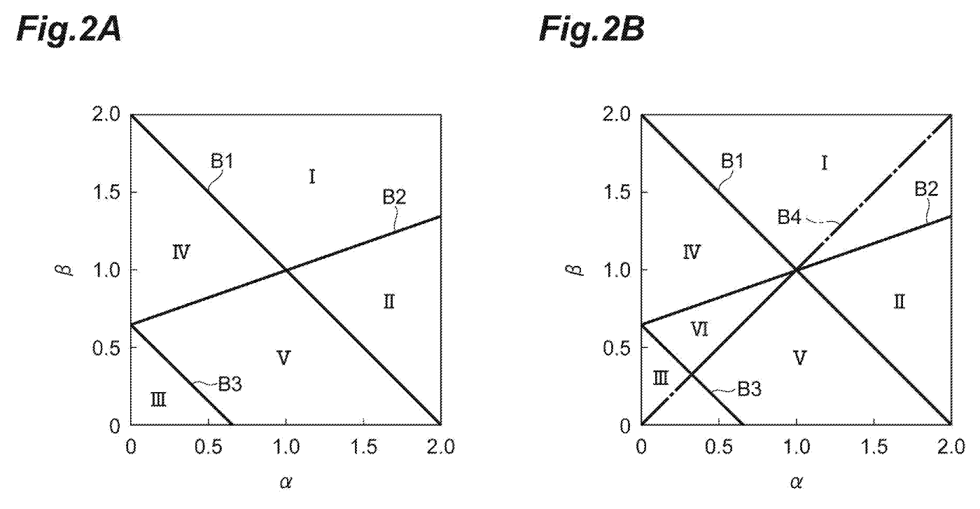

FIG. 2A is a diagram schematically showing the relationship between the values of α and β and the regions I to V in Co₂Mn_{α}Si_{β} which is a type of Heusler alloy represented by Formula (1). In FIG. 2A, α on the abscissa varies in the range of 0<α<2, and β on the ordinate varies in the range of 0<β<2.

The Heusler alloy Co₂Mn_{α}Si_{β} can include a boundary line B1 representing α+β=2, a boundary line B2 representing β=(2+α)/3, and a boundary line B3 representing α+β=⅔. The boundary line B1 corresponds to a composition in which the total ratio of Mn and Si in Co₂Mn_{α}Si_{β} is ½. The boundary line B2 corresponds to such a composition that the ratio of Si in Co₂Mn_{α}Si_{β} is ¼. The boundary line B3 corresponds to such a composition that the total ratio of Mn and Si in Co₂Mn_{α}Si_{β} is ¼. These boundary lines B1 to B3 divide the Heusler alloy Co₂Mn_{α}Si_{β} into regions I to V.

The regions I and II are regions defined by the boundary line B1 and both satisfying 2<α+β. The region I is a region that can be distinguished from the region II by the boundary line B2. The region I is a region satisfying 2<α+β and β>(2+α)/3. The region II is a region satisfying 2<α+β and β<(2+α)/3. In both of the region I and the region II, the total ratio of Mn and Si in Co₂Mn_{α}Si_{β} is larger than ½, and the Heusler alloy Co₂Mn_{α}Si_{β} easily contains excess Mn. Since excess Mn is contained, Mn enters the Mn site and easily moves to sites other than the Mn site. For example, formation of Mn_{Si} antisite where Mn enters the Si site and/or formation of Mn_{Co} antisite where Mn enters the Co site are performed. Further, excess Mn easily diffuses into the nonmagnetic spacer layer 36, for example.

The region III is a region defined by the boundary line B3 and satisfying α+β<⅔. In the region III, the area represented by α+β<⅔, the total ratio of Mn and Si in the Heusler alloy Co₂Mn_{α}Si_{β} is less than ¼. Accordingly, in the region III, the composition of the Heusler alloy Co₂Mn_{α}Si_{β} largely deviates from the stoichiometric composition, making it difficult to increase the spin polarizability.

The regions IV and V are regions defined by the boundary lines B1 and B3 and both satisfying ⅔<α+β<2. The region IV is a region that is distinguished from the region V by the boundary line B2. The region IV satisfies ⅔<α+β<2 and β>(2+α)/3. The region V satisfies ⅔<α+β<2 and β<(2+α)/3. In both of the region IV and the region V, α+β<2 holds and the total ratio of Mn and Si in Co₂Mn_{α}Si_{β} is smaller than ½, and thus the Heusler alloy Co₂Mn_{α}Si_{β} hardly contains excess Mn. In the regions IV and V, Mn easily enters the Mn site correctly while excess Mn is hardly contained, so that Co easily enters the Mn site to form a Co_{Mn} antisite, thereby suppressing the diffusion of Mn into the nonmagnetic spacer layer 36. In both of the regions IV and V, the total ratio of Mn and Si in the Heusler alloy Co₂Mn_{α}Si_{β} is greater than ¼. Accordingly, the composition of the Heusler alloy Co₂Mn_{α}Si_{β} does not largely deviate from the stoichiometric composition, so that the spin polarizability easily increases. The resulting magnetoresistive effect element 1 provides large magnetoresistive effect.

In the region IV, the ratio of Si in Co₂Mn_{α}Si_{β} is different from that in the region V. In the region IV, β>(2+α)/3 is satisfied and the ratio of Si in Co₂Mn_{α}Si_{β} is greater than ¼. In the region V, β<(2+α)/3 is satisfied and the ratio of Si in Co₂Mn_{α}Si_{β} is less than ¼.

In the region IV, the ratio of Si in Co₂Mn_{α}Si_{β} is greater than ¼, so that Si easily enters Mn to form a Si_{Mn} antisite. In the region V, the ratio of Si in Co₂Mn_{α}Si_{β} is less than ¼, so that Mn easily enters Si site to form a Mn_{Si} antisite. In the region V, movement of Mn is more easily limited within the crystalline structure of the Heusler alloy Co₂Mn_{α}Si_{β} layer, thereby further suppressing diffusion of Mn into areas other than the Heusler alloy layer.

FIG. 2B is a diagram schematically showing the relationship between the values of α and β and the regions I to VI in the Heusler alloy Co₂Mn_{α}Si_{β}, and differs from FIG. 2A in that it additionally includes a boundary line B4 ((β=α) and a region VI. As shown in FIG. 2B, the Heusler alloy Co₂Mn_{α}Si_{β} additionally includes the region VI, which is made with the boundary line B4 (β=α), in the region V. The region VI is a region satisfying ⅔<α+β<2, β<(2+α)/3, and β>α. In the region VI, β>α is satisfied and Mn is less than Si, so that movement of Mn to the nonmagnetic spacer layer 36 is further suppressed, thereby further increasing magnetoresistive effect.

In this embodiment, in the first ferromagnetic layer 31 and the second ferromagnetic layer 32, the crystalline structure of the Heusler alloy can be a structure A2, structure B2, or structure L2₁. A Heusler alloy with the structure B2, which has higher spin polarizability than the Heusler alloy with the structure A2, is preferable, and a Heusler alloy with the structure L2₁, which has higher spin polarizability than the Heusler alloy with the structure B2, is more preferable.

For, among Heusler alloys, Heusler alloys with the structures B2 and L2₁, which have a particularly ordered crystalline structure, heat treatment (annealing treatment) is performed for ordering the crystals of the Heusler alloy during fabrication of the magnetoresistive effect element 1. Mn in the Heusler alloy easily diffuses into the nonmagnetic spacer layer 36 during heat treatment, while in this embodiment, the Heusler alloy X₂Mn_{α}Z_{β} represented by Formula (1) is contained. Accordingly, diffusion of Mn in the Heusler alloy into the nonmagnetic spacer layer 36 is suppressed, and thus the magnetoresistive effect element 1 after heat treatment exhibits large magnetoresistive effect.

Referring back to FIG. 1, the magnetoresistive effect element 1 will be described. The magnetoresistance layer 30 may have the nonmagnetic spacer layer 36 between the first ferromagnetic layer 31 and the second ferromagnetic layer 32, and the nonmagnetic spacer layer 36 may contain Ag or Ag-containing metal represented by Formula (A).

Ag_{γ}L_{1-γ} (A)

In Formula (A), X is at least one element selected from the group consisting of Al, Cu, Ga, Ge, As, Y, La, Sm, Yb, and Pt, and 0<γ≤1 is satisfied.

The nonmagnetic spacer layer 36 contains Ag or Ag-containing metal represented by Formula (A), and the lattice constant of Ag or Ag-containing metal can be adjusted by changing the value of L and/or γ of the element. Adjustment of this lattice constant can reduce lattice mismatch between the nonmagnetic spacer layer 36 and the first ferromagnetic layer 31 and/or the second ferromagnetic layer 32. Reducing lattice mismatch improves the crystallinity of the first ferromagnetic layer 31 and/or the second ferromagnetic layer 32 and the nonmagnetic spacer layer 36, thereby producing larger magnetoresistive effect.

The Ag or Ag-containing metal in the nonmagnetic spacer layer 36 tends to have the face-centered cubic lattice structure (fcc structure). For this reason, the nonmagnetic spacer layer 36 and the first ferromagnetic layer 31 and the second ferromagnetic layer 32 can be stacked on each other with high crystal quality. This effect is particularly remarkable when the first ferromagnetic layer 31 and the second ferromagnetic layer 32 also have the fcc structure.

The nonmagnetic spacer layer 36 may contain a metal, such as Cr, Au, V, W, NiAl, AgZn, AgMg, or a nonmagnetic Heusler alloy, instead of Ag or Ag-containing metal represented by Formula (A).

In the magnetoresistance layer 30, the thickness of the nonmagnetic spacer layer 36 is, for example, greater than or equal to 1 nm and less than or equal to 10 nm. The thickness of the first ferromagnetic layer 31 is, for example, greater than or equal to 1 nm and less than or equal to 20 nm. The thickness of the second ferromagnetic layer 32 is, for example, greater than or equal to 1 nm and less than or equal to 20 nm.

The magnetoresistance layer 30 includes an antiferromagnetic layer 35 as needed, and the antiferromagnetic layer 35 is provided, for example, on the surface of the second ferromagnetic layer 32 opposite to the nonmagnetic spacer layer 36 side. The antiferromagneticic layer 35 is used to substantially fix the direction of magnetization of the second ferromagnetic layer 32 by exchange-coupling with the second ferromagnetic layer 32 to give unidirectional anisotropy to the second ferromagnetic layer 32. Examples of material for the antiferromagnetic layer 35 include a FeMn alloy, a PtMn alloy, a PtCrMn alloy, a NiMn alloy, an IrMn alloy, NiO, and Fe₂O₃. The thickness of the antiferromagnetic layer 35 is, for example, 5 nm to 15 nm.

Regarding the first ferromagnetic layer 31 and the second ferromagnetic layer 32, the antiferromagneticic layer 35 is not necessarily provided if the second ferromagnetic layer 32 has a coercive force greater than that of the first ferromagnetic layer 31 and has a level such that the magnetization direction of the second ferromagnetic layer 32 is substantially fixed with respect to the external magnetic field to be measured by a method such as changing the thicknesses of these layers.

In the magnetoresistance layer 30, one of the first ferromagnetic layer 31 and the second ferromagnetic layer 32 is a magnetization free layer, and the other is a magnetization fixed layer: the first ferromagnetic layer 31 may be a magnetization fixed layer, and the second ferromagnetic layer 32 may be a magnetization free layer. In this case, the antiferromagnetic layer 35 is provided on the surface of the first ferromagnetic layer 31 opposite to the nonmagnetic spacer layer 36 side.

The cap layer 40 is provided to protect the magnetoresistance layer 30. The cap layer 40 may contain, for example, one or more metallic elements selected from the group consisting of Ru, Ag, Al, Cu, Au, Cr, Mo, Pt, W, Ta, Pd, and Ir, an alloy of these metallic elements, or a stack body of materials composed of two or more of these metallic elements. An upper electrode for allowing a current to flow in the magnetoresistive effect element 1 along the stacking direction may be provided on the cap layer 40.

The magnetoresistive effect element 1 is fabricated by forming each layer of the base layer 20 to the cap layer 40 on the substrate 10 by a manufacturing method such as sputtering or electron beam evaporation, for example. During formation of each layer, heat treatment may be performed as needed and magnetic field applying treatment for giving unidirectional anisotropy may be performed as needed. During magnetic field applying treatment, heat treatment may be performed concurrently as appropriate. In addition, the magnetoresistive effect element 1 may be fine-patterned into a shape that allows evaluation of magnetoresistive characteristics by lithography using electron beams or the like and dry etching using Ar ions or the like. The magnetoresistive effect element 1 is a magnetoresistive effect element having a current perpendicular to plane (CPP) structure in which a detection current flows along the stacking direction (the direction perpendicular to the film surface of each layer).

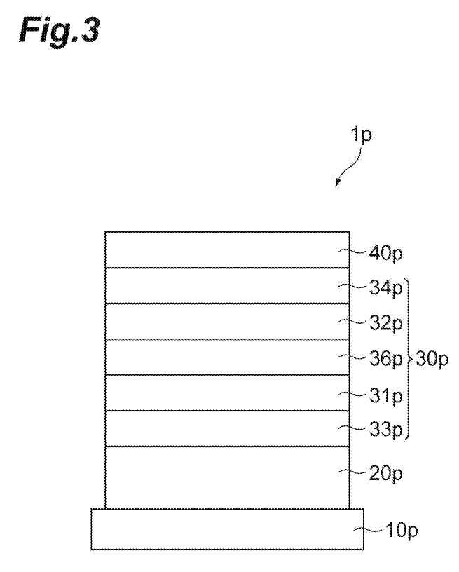

FIG. 3 is a diagram showing the cross section of a magnetoresistive effect element according to a modification of one of the embodiments. A magnetoresistive effect element 1p includes, for example, a substrate 10p, a base layer 20p, a magnetoresistance layer 30p, and a cap layer 40p. The substrate 10p may be similar to the substrate 10 of the magnetoresistive effect element 1, and the base layer 20p may be similar to the base layer 20 of the magnetoresistive effect element 1. Further, the cap layer 40p may be similar to the cap layer 40 of the magnetoresistive effect element 1.

The magnetoresistance layer 30p includes a first ferromagnetic layer 31p serving as a magnetization free layer, a second ferromagnetic layer 32p serving as a magnetization fixed layer, and a nonmagnetic spacer layer 36p provided between the first ferromagnetic layer 31p and the second ferromagnetic layer 32p. The second ferromagnetic layer 32p is provided, for example, on the nonmagnetic spacer layer 36p. At least one of the first ferromagnetic layer 31p and the second ferromagnetic layer 32p contains the Heusler alloy represented by Formula (1). The nonmagnetic spacer layer 36p can contain Ag or Ag-containing metal represented by Formula (A).

In this modification, the magnetoresistance layer 30p can further include at least one of a third ferromagnetic layer 33p and a fourth ferromagnetic layer 34p. The third ferromagnetic layer 33p serves as a magnetization free layer together with the first ferromagnetic layer 31p, and the fourth ferromagnetic layer 34p serves as a magnetization fixed layer together with the second ferromagnetic layer 32p. In the magnetoresistive effect element 1p, the first ferromagnetic layer 31p is provided, for example, between the third ferromagnetic layer 33p and the nonmagnetic spacer layer 36p. The second ferromagnetic layer 32p is provided, for example, between the fourth ferromagnetic layer 34p and the nonmagnetic spacer layer 36p.

In the magnetoresistance layer 30p, the third ferromagnetic layer 33p and the fourth ferromagnetic layer 34p can contain the Heusler alloy represented by Formula (2).

D₂Mn_{δ}E_{θ} (2)

In Formula (2), D represents at least one element selected from the group consisting of Co, Ni, Fe, Ru, and Rh, and E represents at least one element selected from the group consisting of Si, Al, Ga, Ge, Sb, and Sn. In addition, in Formula (2), for δ and θ, 2<δ+θ<2.6 is satisfied. In this embodiment, in Formula (2), X can be Co, and Z can be Si.

In the Heusler alloy Co₂Mn_{δ}Si_{θ} represented by Formula (2), when the Co_{Mf} antisite where Co enters the Mn site is formed, the spin polarizability decreases. On the other hand, the fact that the effect on spin polarizability is small when Mn enters the Co site to form a Mn_{Co} antisite, and when Si enters the Co site to form a Si_{Co} antisite has theoretically been demonstrated.

In the Heusler alloy Co₂Mn_{δ}Si_{θ}, when δ+θ<2, the ratio of Co in Co₂Mn_{α}Si_{β} is greater than ½, and a Co_{Mn} antisite is formed. Accordingly, when δ+θ<2, the spin polarizability decreases. Meanwhile, when 2<δ+θ, a Mn_{Co} antisite where Mn enters the Co site and/or a Si_{Co} antisite where Si enters the Co site are formed, so that the spin polarizability is less affected. In the Heusler alloy Co₂Mn_{δ}Si_{θ}, when 2.6≤δ+θ, the amount of magnetization in the Heusler alloy decreases.

Accordingly, in the Heusler alloy Co₂Mn_{δ}Si_{θ}, when 2<δ+θ<2.6, the effect of the formation of antisites on the spin polarizability decreases, allowing the third ferromagnetic layer 33p and the fourth ferromagnetic layer 34p to easily maintain half metal characteristics. Consequently, the third ferromagnetic layer 33p serves as a magnetization free layer together with the first ferromagnetic layer 31p, so that the spin polarizability of the magnetization free layer increases. Further, the fourth ferromagnetic layer 34p serves as a magnetization fixed layer together with the second ferromagnetic layer 32p, so that the spin polarizability of the magnetization fixed layer increases. The magnetoresistive effect element 1p can provide large magnetoresistive effect.

Regarding the third ferromagnetic layer 33p and the fourth ferromagnetic layer 34p, in the Heusler alloy Co₂Mn_{δ}Si_{θ}, 2<δ+θ<2.6 is satisfied, so that the total ratio of Mn and Si in Co₂Mn_{α}Si_{β} is greater than ½. For this reason, the Heusler alloy Co₂Mn_{δ}Si_{θ} in the third ferromagnetic layer 33p and the fourth ferromagnetic layer 34p contain excess Mn. In this modification, the first ferromagnetic layer 31p provided between the third ferromagnetic layer 33p and the nonmagnetic spacer layer 36p can suppress movement of Mn from the third ferromagnetic layer 33p to the nonmagnetic spacer layer 36p. Further, the second ferromagnetic layer 32p provided between the fourth ferromagnetic layer 34p and the nonmagnetic spacer layer 36p can suppress movement of Mn from the fourth ferromagnetic layer 34p to the nonmagnetic spacer layer 36p.

The thickness of the first ferromagnetic layer 31p is, for example, 1 nm to 20 nm. The thickness of the second ferromagnetic layer 32p is, for example, 1 nm to 20 nm. The thickness of the third ferromagnetic layer 33p is, for example, 1 nm to 20 nm. The thickness of the fourth ferromagnetic layer 34p is, for example, 1 nm to 20 nm. The thickness of the nonmagnetic spacer layer 36p is, for example, greater than or equal to 1 nm and less than or equal to 10 nm.

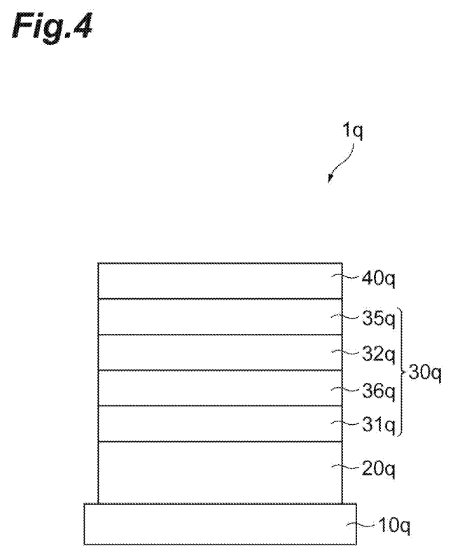

FIG. 4 is a diagram showing the cross section of a magnetoresistive effect element according to another embodiment. A magnetoresistive effect element 1q includes, for example, a substrate 10q, a base layer 20q, a magnetoresistance layer 30q, and a cap layer 40q, in this order.

The magnetoresistance layer 30q includes a first ferromagnetic layer 31q serving as a magnetization free layer, a second ferromagnetic layer 32q serving as a magnetization fixed layer, and a nonmagnetic spacer layer 36q provided between the first ferromagnetic layer 31q and the second ferromagnetic layer 32q. The second ferromagnetic layer 32q is provided, for example, on the nonmagnetic spacer layer 36q.

At least one of the first ferromagnetic layer 31q and the second ferromagnetic layer 32q contains the Heusler alloy represented by Formula (3).

X₂(Mn_{ε}G_{η})_{α}Z_{β} (3)

In Formula (3), X represents at least one element selected from the group consisting of Co, Ni, Fe, Ru, and Rh, and G represents at least one of the elements of Fe and Cr. Note that when G contains Fe, X does not contain Fe. In other words, X represents at least one element selected from the group consisting of Co, Ni, Ru, and Rh. Z represents at least one element selected from the group consisting of Si, Al, Ga, Ge, Sb, and Sn, and ⅔<α+β<2, 0<ε<1, and 0<η<1 are satisfied.

The substrate 10q, the base layer 20q, the magnetoresistance layer 30q, and the cap layer 40q of the magnetoresistive effect element 1q may be similar to the substrate 10, the base layer 20, the magnetoresistance layer 30, and the cap layer 40 of the magnetoresistive effect element 1, respectively.

Since one of the first ferromagnetic layer 31q and the second ferromagnetic layer 32q of the magnetoresistance layer 30q is a magnetization free layer, and the other is a magnetization fixed layer, the first ferromagnetic layer 31q may be a magnetization fixed layer, and the second ferromagnetic layer 32q may be a magnetization free layer. In this case, the antiferromagnetic layer 35q is provided, for example, on the surface of the first ferromagnetic layer 31q opposite to the nonmagnetic spacer layer 36q. The first ferromagnetic layer 31q and the second ferromagnetic layer 32q can be formed by co-sputtering using a CoMnSi alloy target and a Fe target. The composition ratio of Fe in the first ferromagnetic layer 31q and the second ferromagnetic layer 32q is controlled, for example, by the sputtering output during film formation.

In this embodiment, in Formula (3), X can be Co. In a Heusler alloy, in which X is Co, the Curie temperature is sufficiently higher than room temperature, so that large magnetoresistive effect is produced even at room temperature. In addition, in Formula (3), Z can be Si. In a Heusler alloy containing Si, the Curie temperature is high, so that large magnetoresistive effect is produced even at room temperature.

The relationship between the values of α and β in the Heusler alloy Co₂Mn_{α}Si_{β} and the level of magnetoresistive effect in the magnetoresistive effect element 1 can be applied to the Heusler alloy X₂(Mn_{ε}G_{η})_{α}Z_{β} of the magnetoresistive effect element 1q. In other words, the relationship between the values of α and β and the regions I to V in FIGS. 2A and 2B can be applied to the Heusler alloy X₂(Mn_{ε}G_{η})_{α}Z_{β} of the magnetoresistive effect element 1q.

Accordingly, in the Heusler alloy X₂(Mn_{ε}G_{η})_{α}Z_{β} in this magnetoresistive effect element 1q, α+β<2 and 0<g<1 are satisfied and the total ratio of Mn and Z in X₂(Mn_{ε}G_{η})_{α}Z_{β} is smaller than ½, so that the Heusler alloy X₂(Mn_{ε}G_{η})_{α}Z_{β} hardly contains excess Mn. Accordingly, Mn easily enters the Mn site correctly while excess Mn is hardly contained, so that X easily enters the Mn site to form a X_{Mn} antisite, thereby suppressing the diffusion of Mn into the nonmagnetic spacer layer. In addition, in the Heusler alloy X₂(Mn_{ε}G_{η})_{α}Z_{β}, ⅔<α+β is satisfied and the total ratio of Mn, G, and Z in the Heusler alloy X₂(Mn_{ε}G_{η})_{α}Z_{β} can be greater than ¼. Accordingly, the composition of the Heusler alloy X₂(Mn_{ε}G_{η})_{α}Z_{β} does not largely deviate from the stoichiometric composition, so that the spin polarizability easily increases. The resulting magnetoresistive effect element provides large magnetoresistive effect.

In addition, in the magnetoresistive effect element 1q according to this modification, in Formula (3), β<(2+α)/3 may be satisfied. In this magnetoresistive effect element 1q, the ratio of Z in the Heusler alloy X₂(Mn_{ε}G_{η})_{α}Z_{β} is less than ¼, so that Mn easily enters the Z site to form a Mn_{Z} antisite. Movement of Mn more easily stays within the crystalline structure of the Heusler alloy X₂(Mn_{ε}G_{η})_{α}Z_{β} layer, thereby further suppressing diffusion of Mn into area other than the Heusler alloy layer.

In the magnetoresistive effect element 1q according to this modification, in Formula (3), β>α may be satisfied. In this magnetoresistive effect element 1q, β>α and 0<ε<1 are satisfied and Mn is less than Z, so that movement of Mn into the nonmagnetic spacer layer is further suppressed.

In the magnetoresistive effect element 1q according to this modification, in Formula (3), Z may be Si. In this magnetoresistive effect element 1q, when the Heusler alloy contains Si, the Curie temperature is high, so that large magnetoresistive effect is produced even at room temperature.

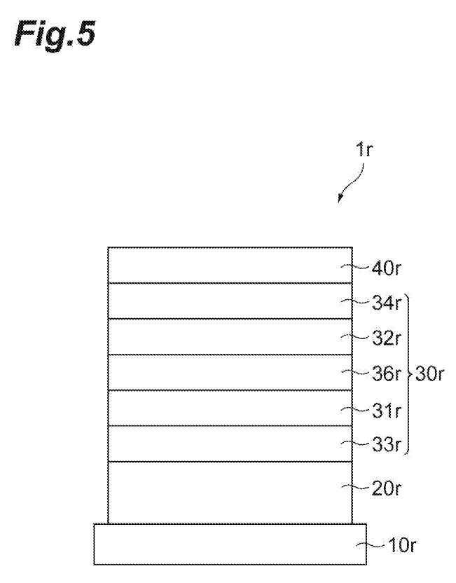

FIG. 5 is a diagram showing the cross section of a magnetoresistive effect element according to a modification of another embodiment. A magnetoresistive effect element Ir includes, for example, a substrate 10r, a base layer 20r, a magnetoresistance layer 30r, and a cap layer 40r. The substrate 10r, the base layer 20r, the magnetoresistance layer 30r, and the cap layer 40r of the magnetoresistive effect element Ir may be similar to the substrate 10, the base layer 20, the magnetoresistance layer 30, and the cap layer 40 of the magnetoresistive effect element 1, respectively.

The magnetoresistance layer 30r includes a first ferromagnetic layer 31r serving as a magnetization free layer, a second ferromagnetic layer 32r serving as a magnetization fixed layer, and a nonmagnetic spacer layer 36r provided between the first ferromagnetic layer 31r and the second ferromagnetic layer 32r. The second ferromagnetic layer 32r is provided, for example, on the nonmagnetic spacer layer 36r. At least one of the first ferromagnetic layer 31r and the second ferromagnetic layer 32r contains the Heusler alloy represented by Formula (3). The nonmagnetic spacer layer 36r can contain Ag or Ag-containing metal represented by Formula (A).

In this modification, the magnetoresistance layer 30r can further include at least one of a third ferromagnetic layer 33r and a fourth ferromagnetic layer 34r. The third ferromagnetic layer 33r serves as a magnetization free layer together with the first ferromagnetic layer 31r, and the fourth ferromagnetic layer 34r serves as a magnetization fixed layer together with the second ferromagnetic layer 32r. In the magnetoresistive effect element Ir, the first ferromagnetic layer 31r is provided, for example, between the third ferromagnetic layer 33r and the nonmagnetic spacer layer 36r. The second ferromagnetic layer 32r is provided, for example, between the fourth ferromagnetic layer 34r and the nonmagnetic spacer layer 36r.

In the magnetoresistance layer 30r, the third ferromagnetic layer 33r and the fourth ferromagnetic layer 34r can contain the Heusler alloy represented by Formula (4).

D₂(Mn_{ε}G_{η})_{δ}E_{θ} (4)

In Formula (4), D represents at least one element selected from the group consisting of Co, Ni, Fe, Ru, and Rh, and G represents at least one of the elements of Fe and Cr. When G contains Fe, D does not contain Fe. In other words, D represents at least one element selected from the group consisting of Co, Ni, Ru, and Rh. E represents at least one element selected from the group consisting of Si, Al, Ga, Ge, Sb, and Sn, and 2<δ+θ<2.6, 0<ε<1, and 0<l<1 are satisfied. In this modification, in Formula (4), X can be Co, and Z can be Si.

In the Heusler alloy Co₂(Mn_{ε}G_{η})_{δ}Si_{θ} represented by Formula (4), like the Heusler alloy Co₂Mn_{δ}Si_{θ}, when 2<δ+θ<2.6, the effect of the formation of antisites on the spin polarizability decreases, allowing the third ferromagnetic layer 33r and the fourth ferromagnetic layer 34r to easily maintain half metal characteristics. Consequently, the third ferromagnetic layer 33r serves as a magnetization free layer together with the first ferromagnetic layer 31r, and the spin polarizability of the magnetization free layer increases. Further, the fourth ferromagnetic layer 34r serves as a magnetization fixed layer together with the second ferromagnetic layer 32r, so that the spin polarizability of the magnetization fixed layer increases. The magnetoresistive effect element Ir can provide large magnetoresistive effect.

Regarding the third ferromagnetic layer 33r and the fourth ferromagnetic layer 34r, in the Heusler alloy Co₂Mn_{δ}Si_{θ}, 2<δ+θ<2.6 is satisfied, so that the total ratio of Mn, G, and Si in Co₂(Mn_{ε}G_{η})_{α}Si_{β} is greater than ½. For this reason, the Heusler alloy Co₂(Mn_{ε}G_{η})_{α}Si_{θ} in the third ferromagnetic layer 33r and the fourth ferromagnetic layer 34r can contain excess Mn. In this embodiment, the first ferromagnetic layer 31r provided between the third ferromagnetic layer 33r and the nonmagnetic spacer layer 36r can suppress movement of Mn from the third ferromagnetic layer 33r to the nonmagnetic spacer layer 36r. Further, the second ferromagnetic layer 32r provided between the fourth ferromagnetic layer 34r and the nonmagnetic spacer layer 36r can suppress movement of Mn from the fourth ferromagnetic layer 34r to the nonmagnetic spacer layer 36r.

The thickness of the first ferromagnetic layer 31r is, for example, 1 nm to 20 nm. The thickness of the second ferromagnetic layer 32r is, for example, 1 nm to 20 nm. The thickness of the third ferromagnetic layer 33r is, for example, 1 nm to 20 nm. The thickness of the fourth ferromagnetic layer 34r is, for example, 1 nm to 20 nm. The thickness of the nonmagnetic spacer layer 36r is, for example, greater than or equal to 1 nm and less than or equal to 10 nm.

In the magnetoresistive effect element Ir according to this modification, the nonmagnetic spacer layer may contain Ag or Ag-containing metal represented by Formula (A).

Ag_{γ}L_{1-γ} (A)

In Formula (A), L is at least one element selected from the group consisting of Al, Cu, Ga, Ge, As, Y, La, Sm, Yb, and Pt, and 0<γ≤1 is satisfied.

In this magnetoresistive effect element Ir, the nonmagnetic spacer layer 36r contains Ag or Ag-containing metal represented by Formula (A), and the lattice constant of Ag or Ag-containing metal can be adjusted by changing the value of L and/or γ of the element. Adjustment of this lattice constant can reduce lattice mismatch between the nonmagnetic spacer layer 36r and the first ferromagnetic layer 31r and/or the second ferromagnetic layer 32r. Reducing lattice mismatch improves the crystallinity of the first ferromagnetic layer 31r and/or the second ferromagnetic layer 32r and the nonmagnetic spacer layer 36r, thereby producing larger magnetoresistive effect.

### EXAMPLE

A magnetoresistive effect element will now be further described with examples and comparative examples of the present disclosure, but the present disclosure should not be limited to the examples below.

Table 1 collectively shows the values of α, β, α+β, and (2+α)/3, and magnetoresistive ratios (MR ratios) (%) related to the magnetoresistive effect elements according to Examples 1 and 2 and Comparative Examples 1 and 2 fabricated as described later.

The MR ratio related to each magnetoresistive effect element was estimated from the magnitude of the measured magnetic resistance. The MR ratio is expressed in percentage and was obtained by Formula (5) below.

MR ratio (%)=((R_{AP}−_{P})/R_{P})×100(%) (5)

In this Formula (5), R_{AP} is the magnitude of the resistance of the magnetoresistive effect element in the state where the direction of the magnetization of the first ferromagnetic layer and the direction of the magnetization of the second ferromagnetic layer are antiparallel to each other. R_{P} is the magnitude of the resistance of the magnetoresistive effect element in the state where the direction of the magnetization of the first ferromagnetic layer and the direction of the magnetization of the second ferromagnetic layer are parallel to each other.

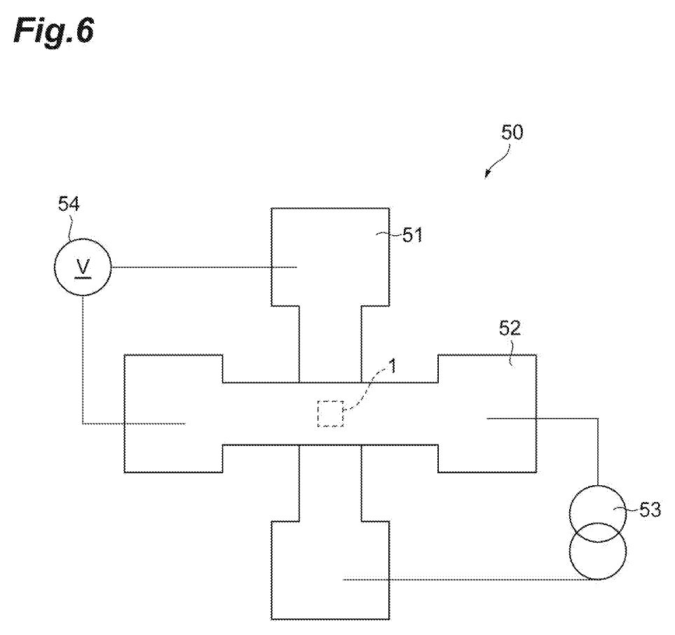

FIG. 6 is a diagram showing a magnetoresistance device capable of evaluating the MR ratio of the magnetoresistive effect element. A magnetoresistance device 50 includes a first electrode layer 51 and a second electrode layer 52 between which a magnetoresistive effect element 1 is sandwiched. The magnetoresistive effect element 1 is fine-patterned into a shape suitable for measurement of magnetoresistive characteristics. The first electrode layer 51 is connected to the base layer 20 on the substrate 10 of the magnetoresistive effect element 1, and the second electrode layer 52 is connected to the cap layer 40 of the magnetoresistive effect element 1. The magnetoresistance device further includes a power source 53 and a voltmeter 54. The power source 53 and the voltmeter 54 are both connected to the first electrode layer 51 and the second electrode layer 52. Current is supplied from the power source 53 to the magnetoresistive effect element 1 along the stacking direction, and the voltage applied to the magnetoresistive effect element 1 at the time can be monitored with the voltmeter 54. Changes in the resistance of the magnetoresistive effect element 1 can be measured by monitoring the voltage applied to the magnetoresistive effect element 1 with the voltmeter 54 while sweeping the magnetic field from an external device to the magnetoresistive effect element 1 in the state where a constant current is applied to the magnetoresistive effect element 1 in the stacking direction. The MR ratio related to the magnetoresistive effect element 1 can be calculated from the results of measurement of changes in this resistance.

### Example 1

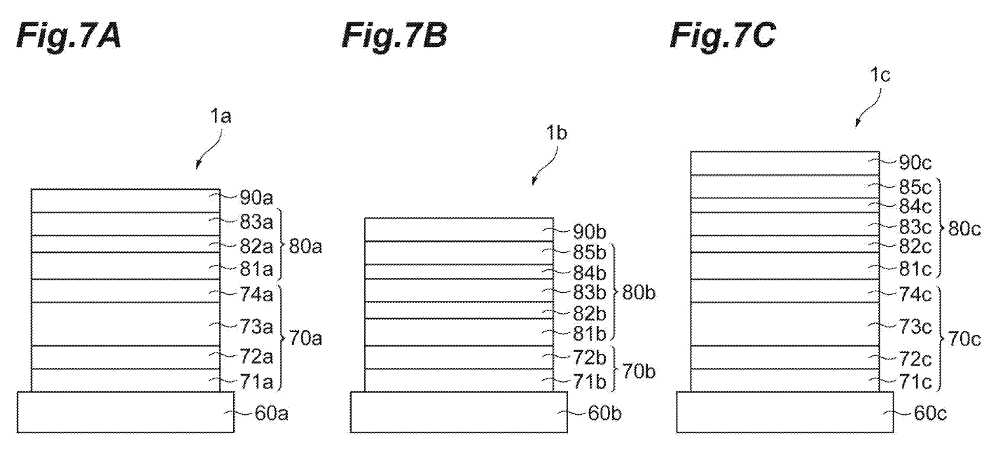

FIG. 7A is a diagram showing the cross section of a magnetoresistive effect element according to Example 1. In Example 1, a magnetoresistive effect element 1a was fabricated in the following procedure. To be specific, a base layer 70a was first formed on a MgO substrate 60a. To be specific, a MgO buffer layer 71a (having a thickness of 10 nm) was formed on the MgO substrate 60a through electron beam evaporation. The MgO buffer layer 71a was formed at a temperature of 600° C. Heat treatment (at a temperature of 600° C.) was performed after the formation of the MgO buffer layer 71a. Subsequently, a CoFe seed layer 72a (having a thickness of 10 nm) was formed on the MgO buffer layer 71a by sputtering. The CoFe seed layer 72a was formed at room temperature. Heat treatment was not performed after the formation of the CoFe seed layer 72a. Subsequently, an Ag buffer layer 73a (having a thickness of 100 nm) was formed on the CoFe seed layer 72a. The Ag buffer layer 73a was formed at room temperature. Heat treatment (at a temperature of 300° C.) was performed after the formation of the Ag buffer layer 73a. Subsequently, a CoFe buffer layer 74a (having a thickness of 10 nm) was formed on the Ag buffer layer 73a. The CoFe buffer layer 74a was formed at room temperature. Heat treatment was not performed after the formation of the CoFe buffer layer 74a.

Subsequently, a magnetoresistance layer 80a was formed on the base layer 70a by sputtering. To be specific, a first ferromagnetic layer 81a (having a thickness of 10 nm) and an Ag layer (having a thickness of 5 nm) serving as the nonmagnetic spacer layer 82a were formed in this order on the CoFe buffer layer 74a of the base layer 70a. These two layers were formed at room temperature. Heat treatment was not performed after the formation of these two layers. Subsequently, a second ferromagnetic layer 83a (having a thickness of 3 nm) was formed on the nonmagnetic spacer layer 82a. The second ferromagnetic layer 83a was formed at room temperature. Heat treatment (at a temperature of 550° C.) was performed after the formation of the second ferromagnetic layer 83a. The first ferromagnetic layer 81a and the second ferromagnetic layer 83a were both Co₂Mn_{α}Si_{β} layers and the values of α and β were as shown in Table 1.

Subsequently, a cap layer 90a was formed on the magnetoresistance layer 80a by electron beam evaporation. To be specific, a Ru layer (having a thickness of 5 nm) serving as the cap layer 90a was formed on the second ferromagnetic layer 83a of the magnetoresistance layer 80a. The cap layer 90a was formed at room temperature. Heat treatment was not performed after the formation of the cap layer 90a.

### Example 2

In Example 2, fabrication of a magnetoresistive effect element and estimation of the MR ratio were performed in the same procedure of fabrication and estimation of Example 1. The first ferromagnetic layer and the second ferromagnetic layer in Example 2 were both Co₂Mn_{α}Si_{β} layers and the values of α and β were as shown in Table 1.

### Comparative Examples 1 and 2

In Comparative Examples 1 and 2, fabrication of a magnetoresistive effect element and estimation of the MR ratio were performed in the same procedure of fabrication and estimation of Example 1. Both the first ferromagnetic layer and the second ferromagnetic layer in Comparative Examples 1 and 2 were Co₂Mn_{α}Si_{β} layers and the values of α and β were as shown in Table 1.

TABLE 1

| | | | | | MR |
|---|---|---|---|---|---|
| | α | β | α + β | (2 + α)/3 | ratio (%) |
| Example 1 | 0.62 | 0.82 | 1.44 | 0.87 | 17.5 |
| Example 2 | 0.9 | 0.82 | 1.72 | 0.97 | 12.8 |
| Comparative Example 1 | 1.2 | 0.82 | 2.02 | 1.07 | 10.4 |
| Comparative Example 2 | 1.4 | 0.82 | 2.22 | 1.13 | 6.7 |

As shown in Table 1, the magnetoresistive effect elements according to Examples 1 and 2 have larger MR ratios than the magnetoresistive effect elements according to Comparative Examples 1 and 2. Further, the magnetoresistive effect element according to Example 1 has a larger MR ratio than the magnetoresistive effect element according to Example 2. In Examples 1 and 2, ⅔<α+β<2 and β<(2+α)/3 are satisfied. In Example 1, β >α is further satisfied.

Table 2 collectively shows the values of α, β, α+β, and (2+α)/3, and MR ratios (%) related to the magnetoresistive effect elements according to Examples 3 and 4 and Comparative Example 3 fabricated as described later.

### Example 3

FIG. 7B is a diagram showing the cross section of a magnetoresistive effect element according to Example 3. In Example 3, a magnetoresistive effect element 1b was fabricated in the following procedure. To be specific, a base layer 70b was first formed on a MgO substrate 60b. To be specific, a MgO buffer layer 71b (having a thickness of 10 nm) was formed on the MgO substrate 60b through electron beam evaporation. The MgO buffer layer 71b was formed at a temperature of 400° C. Heat treatment was not performed after the formation of the MgO buffer layer 71b. Subsequently, a CoFe buffer layer 72b (having a thickness of 30 nm) was formed on the MgO buffer layer 71b by sputtering. The CoFe buffer layer 72b was formed at room temperature. Heat treatment (at a temperature of 500° C.) was performed after the formation of the CoFe buffer layer 72b.

Subsequently, a magnetoresistance layer 80b was formed on the base layer 70b by sputtering. To be specific, a first ferromagnetic layer 81b (having a thickness of 3 nm) was formed on the CoFe buffer layer 72b of the base layer 70b. The first ferromagnetic layer 81b was formed at room temperature. After the formation of the first ferromagnetic layer 81b, heat treatment (at a temperature of 500° C.) was performed. Subsequently, an Ag layer (having a thickness of 5 nm) serving as the nonmagnetic spacer layer 82b was formed on the first ferromagnetic layer 81b. The nonmagnetic spacer layer 82b was formed at room temperature. Heat treatment was not performed after the formation of the nonmagnetic spacer layer 82b. Subsequently, a second ferromagnetic layer 83b (having a thickness of 3 nm) was formed on the nonmagnetic spacer layer 82b. The second ferromagnetic layer 83b was formed at room temperature. After the formation of the second ferromagnetic layer 83b, heat treatment (at a temperature of 500° C.) was performed. Subsequently, a CoFe buffer layer 84b (having a thickness of 1.1 nm) and an IrMn layer (having a thickness of 10 nm) serving as the antiferromagnetic layer 85b were formed in this order on the second ferromagnetic layer 83b by sputtering. These two layers were formed at room temperature. Heat treatment was not performed after the formation of these two layers. The first ferromagnetic layer 81b and the second ferromagnetic layer 83b were Co₂Mn_{α}Si_{β} layers and the values of α and β were as shown in Table 2.

Subsequently, a cap layer 90b was formed on the magnetoresistance layer 80b by sputtering. To be specific, a Ru layer (having a thickness of 5 nm) serving as the cap layer 90b was formed on the antiferromagnetic layer 85b of the magnetoresistance layer 80b. The cap layer 90b was formed at room temperature. Heat treatment was not performed after the formation of the cap layer 90b.

In Example 3, after the formation of the magnetoresistive effect element 1b, heat treatment was performed in the magnetic field to impart unidirectional anisotropy to the second ferromagnetic layer. The heat treatment temperature for this heat treatment in the magnetic field was 325° C., and the magnitude of the applied magnetic field was 5k Oe (399 kA/m).

### Example 4

In Example 4, fabrication of a magnetoresistive effect element and estimation of the MR ratio were performed in the same procedure as that of fabrication and estimation of Example 3. The first ferromagnetic layer and the second ferromagnetic layer in Example 4 were Co₂Mn_{α}Si_{β} layers and the values of α and β were as shown in Table 2.

### Comparative Example 3

In Comparative Example 3, fabrication of a magnetoresistive effect element and estimation of the MR ratio were performed in the same procedure as that of fabrication and estimation of Example 3. The first ferromagnetic layer and the second ferromagnetic layer in Comparative Example 3 were Co₂Mn_{α}Si_{β} layers and the values of α and β were as shown in Table 2.

TABLE 2

| | | | | | MR |
|---|---|---|---|---|---|
| | α | β | α + β | (2 + α)/3 | ratio (%) |
| Example 3 | 0.74 | 0.9 | 1.64 | 0.91 | 8.9 |
| Example 4 | 1.0 | 0.9 | 1.9 | 1.0 | 6.2 |
| Comparative Example 3 | 1.24 | 0.9 | 2.14 | 1.08 | 4.9 |

As shown in Table 2, the magnetoresistive effect elements according to Examples 3 and 4 have larger MR ratios than the magnetoresistive effect elements according to Comparative Example 3. Further, the magnetoresistive effect element according to Example 3 has a larger MR ratio than the magnetoresistive effect element according to Example 4. In Examples 3 and 4, ⅔<α+β<2 and β<(2+α)/3 are satisfied. In Example 3, β>α is further satisfied.

### Example 5

FIG. 7C is a diagram showing the cross section of a magnetoresistive effect element according to Example 5. In Example 5, a magnetoresistive effect element 1c was fabricated in the following procedure. To be specific, a base layer 70c was first formed on a MgO substrate 60c in the same procedure as in Example 1. Subsequently, a magnetoresistance layer 80c was formed on the base layer 70c by sputtering. To be specific, a third ferromagnetic layer 81c (having a thickness of 10 nm), a first ferromagnetic layer 82c (having a thickness of 1.1 nm), an Ag layer (having a thickness of 5 nm) serving as the nonmagnetic spacer layer 83c, and the second ferromagnetic layer 84c (having a thickness of 1.1 nm) were formed in this order on the CoFe buffer layer 74c of the base layer 70c. These four layers were formed at room temperature. Heat treatment was not performed after the formation of these four layers. Subsequently, a fourth ferromagnetic layer 85c (having a thickness of 3 nm) was formed on the second ferromagnetic layer 84c. The fourth ferromagnetic layer 85c was formed at room temperature. After the formation of the fourth ferromagnetic layer 85c, heat treatment (at a temperature of 550° C.) was performed. The first ferromagnetic layer 82c and the second ferromagnetic layer 84c were Co₂Mn_{α}Si_{β} layers and the values of a and R were 0.68 and 0.82, respectively. In addition, both the third ferromagnetic layer 81c and the fourth ferromagnetic layer 85c were Co₂Mn_{δ}Si_{θ} layers. In the third ferromagnetic layer 81c and the fourth ferromagnetic layer 85c, the values of 6 and 0 were 1.4 and 0.82, respectively.

Subsequently, a cap layer 90c was formed on the magnetoresistance layer 80c by electron beam evaporation. To be specific, a Ru layer (having a thickness of 5 nm) serving as the cap layer 90c was formed on the fourth ferromagnetic layer 85c of the magnetoresistance layer 80c. The cap layer 90c was formed at room temperature. Heat treatment was not performed after the formation of the cap layer 90c.

### Example 6

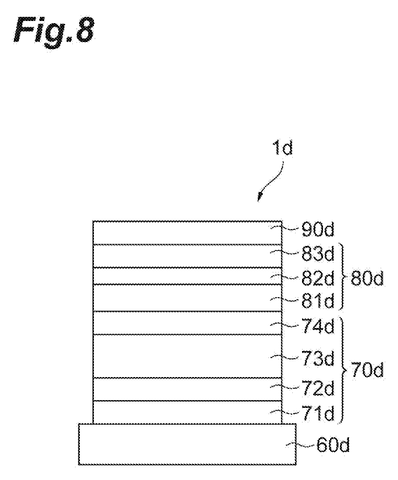

FIG. 8 is a diagram showing the cross section of a magnetoresistive effect element according to Example 6. In Example 6, a magnetoresistive effect element 1d was fabricated in the following procedure. To be specific, a base layer 70d was first formed on a MgO substrate 60d. To be specific, a MgO buffer layer 71d (having a thickness of 10 nm) was formed on the MgO substrate 60d through electron beam evaporation. The MgO buffer layer 71d was formed at a temperature of 600° C. Heat treatment (at a temperature of 600° C.) was performed after the formation of the MgO buffer layer 71d. Subsequently, a CoFe seed layer 72d (having a thickness of 10 nm) was formed on the MgO buffer layer 71d by sputtering. The CoFe seed layer 72d was formed at room temperature. Heat treatment was not performed after the formation of the CoFe seed layer 72d.

Subsequently, an Ag buffer layer 73d (having a thickness of 100 nm) was formed on the CoFe seed layer 72d. The Ag buffer layer 73d was formed at room temperature. Heat treatment (at a temperature of 300° C.) was performed after the formation of the Ag buffer layer 73d. Subsequently, a CoFe buffer layer 74d (having a thickness of 10 nm) was formed on the Ag buffer layer 73d. The CoFe buffer layer 74d was formed at room temperature. Heat treatment was not performed after the formation of the CoFe buffer layer 74d.

Subsequently, a magnetoresistance layer 80d was formed on the base layer 70d by sputtering. To be specific, a first ferromagnetic layer 81d (having a thickness of 10 nm) and an Ag layer (having a thickness of 5 nm) serving as the nonmagnetic spacer layer 82d were formed in this order on the CoFe buffer layer 74d of the base layer 70d. The first ferromagnetic layer 81d was formed by co-sputtering using a CoMnSi alloy target and a Fe target. The two layers: first ferromagnetic layer 81d and the nonmagnetic spacer layer 82d were formed at room temperature, and heat treatment was not performed after the formation of these two layers. Subsequently, a second ferromagnetic layer 83d (having a thickness of 3 nm) was formed on the nonmagnetic spacer layer 82d. The second ferromagnetic layer 83d was formed by co-sputtering using a CoMnSi alloy target and a Fe target. The ratio of Fe in the first ferromagnetic layer 81d and the second ferromagnetic layer 83d was controlled by the sputtering output during film formation. The second ferromagnetic layer 83d was formed at room temperature. After the formation of the second ferromagnetic layer 83d, heat treatment (at a temperature of 550° C.) was performed. The first ferromagnetic layer 81d and the second ferromagnetic layer 83d were Co₂(Mn_{ε}Fe_{η})_{α}Si_{β} layers and the values of ε, η, α, and β were as shown in Table 3.

Subsequently, a cap layer 90d was formed on the magnetoresistance layer 80d by electron beam evaporation. To be specific, a Ru layer (having a thickness of 5 nm) serving as the cap layer 90d was formed on the second ferromagnetic layer 83d of the magnetoresistance layer 80d. The cap layer 90d was formed at room temperature. Heat treatment was not performed after the formation of the cap layer 90d.

### Comparative Examples 4 to 6

In Comparative Examples 4 to 6, fabrication of a magnetoresistive effect element and estimation of the MR ratio were performed in the same procedure as that of fabrication and estimation of Example 6. Both the first ferromagnetic layer and the second ferromagnetic layer in Comparative Examples 4 to 6 were Co₂(Mn_{ε}Fe_{η})Si_{β} layers and the values of Σ, η, α, and β were as shown in Table 3.

TABLE 3

| | | | | | | (2 + α)/ | MR ratio |
|---|---|---|---|---|---|---|---|
| | ε | η | α | β | α + β | 3 | (%) |
| Example 6 | 0.64 | 0.36 | 1.00 | 0.82 | 1.82 | 1.00 | 21.2 |
| Comparative | 0.64 | 0.54 | 1.18 | 0.82 | 2.00 | 1.06 | 19.9 |
| Example 4 | | | | | | | |
| Comparative | 0.64 | 0.72 | 1.36 | 0.82 | 2.18 | 1.12 | 17.4 |
| Example 5 | | | | | | | |
| Comparative | 0.64 | 0.93 | 1.57 | 0.82 | 2.39 | 1.19 | 14.7 |
| Example 6 | | | | | | | |

As shown in Table 3, the magnetoresistive effect element according to Example 6 has a larger MR ratio than the magnetoresistive effect elements according to Comparative Examples 4 to 6. In Example 6, ⅔<α+β<2 and β<(2+α)/3 are satisfied.

### Example 7

In Example 7, fabrication of a magnetoresistive effect element and estimation of the MR ratio were performed in the same procedure as that of fabrication and estimation of Example 6 except that heat treatment was performed at a temperature of 575° C. after the formation of the second ferromagnetic layer 83d. Both the first ferromagnetic layer and the second ferromagnetic layer in Example 7 were Co₂(Mn_{ε}Fe_{η})_{α}Si_{β} layers as in Example 6. The values of ε, η, α, and β in the first ferromagnetic layer and the second ferromagnetic layer were as shown in Table 4.

### Comparative Example 7

In Comparative Example 7, fabrication of a magnetoresistive effect element and estimation of the MR ratio were performed in the same procedure as that of fabrication and estimation of Example 7. The values of ε, η, α, and β in the first ferromagnetic layer and the second ferromagnetic layer were as shown in Table 4.

TABLE 4

| | | | | | | (2 + α)/ | MR ratio |
|---|---|---|---|---|---|---|---|
| | ε | η | α | β | α + β | 3 | (%) |
| Example 7 | 0.64 | 0.36 | 1.00 | 0.82 | 1.82 | 1.00 | 20.2 |
| Comparative | 0.64 | 0.74 | 1.36 | 0.82 | 2.18 | 1.12 | 15.4 |
| Example 7 | | | | | | | |

As shown in Table 4, the magnetoresistive effect element according to Example 7 has a larger MR ratio than the magnetoresistive effect element according to Comparative Example 7. In Example 7, ⅔<α+β<2 and β<(2+α)/3 are satisfied.

As shown in Tables 3 and 4, even if the temperature of heat treatment performed after the formation of the second ferromagnetic layer 83d is changed from 550° C. of Example 6 to 575° C. of Example 7, the MR ratio of Example 7 and the MR ratio of Example 6 both exceed 20%.

The present disclosure has been described so far referring to the embodiments, modifications, and examples, but the present disclosure should not be limited to these embodiments, modifications, and examples and various variations can be made. For example, the magnetoresistive effect element 1 of the embodiments above can have a current in plane (CIP) structure in which a detection current flows along the stacking surface direction, instead of a CPP structure.

The embodiments provide a magnetoresistive effect element in which the ferromagnetic layer of a magnetoresistance layer contains a Heusler alloy containing Mn and which provides large magnetoresistive effect.

What is claimed is:

1. A magnetoresistive effect element comprising:
a first ferromagnetic layer serving as a magnetization free layer;
a second ferromagnetic layer serving as a magnetization fixed layer; and
a nonmagnetic spacer layer provided between the first ferromagnetic layer and the second ferromagnetic layer,
wherein at least one of the first ferromagnetic layer and the second ferromagnetic layer contains a Heusler alloy represented by Formula (1):
X₂Mn_{α}Z_{β} (1)
where X represents at least one element selected from the group consisting of Co, Ni, Fe, Ru, and Rh, and Z represents at least one element selected from the group consisting of Si, Al, Ga, Ge, Sb, and Sn, and ⅔<α+β<2 is satisfied.

2. The magnetoresistive effect element according to claim 1, wherein β<(2+α)/3 is satisfied in the Formula (1).

3. The magnetoresistive effect element according to claim 1, wherein β>α is satisfied in the Formula (1).

4. The magnetoresistive effect element according to claim 1, wherein Z is Si in the Formula (1).

5. The magnetoresistive effect element according to claim 1, further comprising:
at least one of a third ferromagnetic layer serving as a magnetization free layer together with the first ferromagnetic layer, and a fourth ferromagnetic layer serving as a magnetization fixed layer together with the second ferromagnetic layer,
wherein the third ferromagnetic layer and the fourth ferromagnetic layer contain a Heusler alloy represented by Formula (2),
wherein the first ferromagnetic layer is provided between the third ferromagnetic layer and the nonmagnetic spacer layer, and
wherein the second ferromagnetic layer is provided between the fourth ferromagnetic layer and the nonmagnetic spacer layer:
D₂Mn_{δ}E_{θ} (2)
where D represents at least one element selected from the group consisting of Co, Ni, Fe, Ru, and Rh, and E represents at least one element selected from the group consisting of Si, Al, Ga, Ge, Sb, and Sn, and 2<δ+θ<2.6 is satisfied.

6. A magnetoresistive effect element comprising:
a first ferromagnetic layer serving as a magnetization free layer;
a second ferromagnetic layer serving as a magnetization fixed layer; and
a nonmagnetic spacer layer provided between the first ferromagnetic layer and the second ferromagnetic layer,
wherein at least one of the first ferromagnetic layer and the second ferromagnetic layer contains a Heusler alloy represented by Formula (3):
X₂(Mn_{ε}Gη)_{α}Z_{β} (3)
where X represents at least one element selected from the group consisting of Co, Ni, Fe, Ru, and Rh, G represents at least one of the elements of Fe and Cr, X does not contain Fe when G contains Fe, Z represents at least one element selected from the group consisting of Si, Al, Ga, Ge, Sb, and Sn, and ⅔<α+β<2, 0<ε<1, and 0<η<1 are satisfied.

7. The magnetoresistive effect element according to claim 6, wherein β<(2+α)/3 is satisfied in the Formula (3).

8. The magnetoresistive effect element according to claim 6, wherein β>α is satisfied in the Formula (3).

9. The magnetoresistive effect element according to claim 6, wherein Z is Si in the Formula (3).

10. The magnetoresistive effect element according to claim 6, further comprising:
at least one of a third ferromagnetic layer serving as a magnetization free layer together with the first ferromagnetic layer, and a fourth ferromagnetic layer serving as a magnetization fixed layer together with the second ferromagnetic layer,
wherein the third ferromagnetic layer and the fourth ferromagnetic layer contain a Heusler alloy represented by Formula (4),
wherein the first ferromagnetic layer is provided between the third ferromagnetic layer and the nonmagnetic spacer layer, and
wherein the second ferromagnetic layer is provided between the fourth ferromagnetic layer and the nonmagnetic spacer layer:
D₂(Mn_{ε}G_{η})_{δ}E_{θ} (4)
where D represents at least one element selected from the group consisting of Co, Ni, Fe, Ru, and Rh, G represents at least one of the elements of Fe and Cr, D does not contain Fe when G contains Fe, E represents at least one element selected from the group consisting of Si, Al, Ga, Ge, Sb, and Sn, and 2<δ+θ<2.6, 0<ε<1, and 0<η<1 are satisfied.

11. The magnetoresistive effect element according to claim 1, wherein
the nonmagnetic spacer layer contains Ag or Ag-containing metal represented by Formula (A):
Ag_{γ}L_{1-γ} (A)
where L is at least one element selected from the group consisting of Al, Cu, Ga, Ge, As, Y, La, Sm, Yb, and Pt, and 0<γ<1 is satisfied.

12. The magnetoresistive effect element according to claim 2, wherein β>α is satisfied in the Formula (1).

13. The magnetoresistive effect element according to claim 2, wherein Z is Si in the Formula (1).

14. The magnetoresistive effect element according to claim 3, wherein Z is Si in the Formula (1).

15. The magnetoresistive effect element according to claim 12, wherein Z is Si in the Formula (1).

16. The magnetoresistive effect element according to claim 7, wherein β>α is satisfied in the Formula (3).

17. The magnetoresistive effect element according to claim 7, wherein Z is Si in the Formula (3).

18. The magnetoresistive effect element according to claim 8, wherein Z is Si in the Formula (3).

19. The magnetoresistive effect element according to claim 16, wherein Z is Si in the Formula (3).

20. The magnetoresistive effect element according to claim 6, wherein
the nonmagnetic spacer layer contains Ag or Ag-containing metal represented by Formula (A):
Ag_{γ}L_{1-γ} (A)
where L is at least one element selected from the group consisting of Al, Cu, Ga, Ge, As, Y, La, Sm, Yb, and Pt, and 0<γ≤1 is satisfied.
